(19) United States
(12) Patent Application Publication
(10) Pub. No.: US 2008/0130243 A1
(43) Pub. Date: Jun. 5, 2008

(54) Fastening mechanism

(75) Inventor: Lin-Wei Chang, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/607,329

(22) Filed: Nov. 30, 2006

(51) Int. Cl. H05K 7/20

(52) U.S. Cl. 361/720

(57) ABSTRACT

The present invention discloses a fastening mechanism for fastening a heat sink to the surface of an electronic device mounted on a circuit board, the heat sink being provided with a first positioning portion, the circuit board having two opposite sides each formed with a notch. The fastening mechanism at least includes a body for pressing the heat sink on the electronic device, at least two bending portions corresponding in position to and striding over the notches respectively, and at least two snap-fit portions disposed at the end of each of the bending portions and wider than the notches respectively, to enable snap-fit engagement of the snap-fit portions with the edges of the notches of the circuit board, thereby effectively fastening the heat sink to the electronic device.

### BACKGROUND OF THE INVENTION

1. Field of the Invention

The present invention relates to a fastening mechanism, and more particularly, to a fastening mechanism for fastening a heat sink to an electronic device.

2. Description of the Prior Art

With continual advances in electronic technology, the computation function of a computer is becoming more powerful, and computation by a new generation chip is faster than it has ever been before. As a result, chips in operation generate an increasing amount of heat. To prevent heat generated by a chip in operation from damaging the chip or shortening the life of the chip, a heat sink is disposed on the chip as disclosed in the prior art, to transfer any heat generated by the chip in operation to the heat sink, and cool air is driven to the heat sink by fan to speed up heat dissipation.

However, a conventional heat sink is typically fastened to a chip by means of thermally conductive tape or adhesive, though inefficiently; and the heat sink tends to loosen and thereby detach because of computer-induced vibration or when the computer is manually moved. Hence, a fastening mechanism is required to efficiently fasten the heat sink to the chip so as to prevent the heat sink from loosening and detaching.

Referring to FIG. 1, to solve the aforesaid problem, four fasteners 1, such as four pins, are employed to fasten a heat sink 10 to a through hole 11 of a circuit board 13 and thus the heat sink 10 is secured in position to a chip 12 mounted on the circuit board 13; as a result, the heat sink 10 is unlikely to loosen and detach, not to mention that heat dissipation by the heat sink 10 is achieved.

Nonetheless, with a small area of contact between the conventional fastener and a heat sink, no pressing force can be uniformly and consistently applied, and in consequence a chip and the heat sink cannot be pressed together evenly and tightly, and thus heat dissipation of the chip is affected, not to mention that the heat sink is seldom secured in position. In the aforesaid situation, the heat sink is very likely to slide relative to the chip when touched or subjected to vibration during a maintenance operation, thus resulting in a decrease in the area of contact between the heat sink and the chip, and affecting heat dissipation of the chip. In addition, the aforesaid prior art entails using four fasteners to secure in position the heat sink to the chip, which is quite time-consuming and inconvenient to an assembly worker.

Accordingly, an issue calling for urgent solution involves providing a fastening mechanism for fastening a heat sink to a chip conveniently and efficiently.

### SUMMARY OF THE INVENTION

In light of the aforesaid drawbacks of the prior art, it is a primary objective of the present invention to provide a fastening mechanism for effectively fastening a heat sink to an electronic device mounted on a circuit board.

Another objective of the present invention is to provide a fastening mechanism which is easy to mount and dismount.

In order to achieve the above and other objectives, the present invention provides a fastening mechanism for fastening a heat sink to a surface of an electronic device mounted on a circuit board, the heat sink being disposed with a first positioning portion, the circuit board having two opposite sides each disposed with a notch, the fastening mechanism comprising: a body pressing on the heat sink, and having a second positioning portion corresponding in position to the first positioning portion; at least two bending portions disposed at both ends of the body respectively, and corresponding in position to and striding over the notches respectively; and at least two snap-fit portions disposed at both ends of the bending portions respectively, and wider than the notches respectively, for snap-fit engagement with edges of the notches of the circuit board.

The body is a metal board. The first positioning portion and the second positioning portion, both of which correspond in position to each other, are a protruding post and a hole respectively. Preferably, the second positioning portion is centrally disposed in the body. A protruding portion extending outward is centrally disposed in the body. The second positioning portion is disposed in the protruding portion. The bending portions extend and bend downward from both ends of the body. The snap-fit portions extend outward from both ends of the bending portions. Selectively, the fastening mechanism further comprises an operating portion disposed on an outer side of at least one of the snap-fit portions, and the operating portion bends upward from the end of the snap-fit portion and assumes a barb shape.

Compared to the prior art, the present invention discloses a fastening mechanism, wherein two bilaterally disposed snap-fit portions of the fastening mechanism are snapped to a circuit board, and a snap-fit force allows the body of the fastening mechanism to press on a heat sink, thus fastening the heat sink to an electronic device efficiently. In addition, dismounting the fastening mechanism entails mere separation of the snap-fit portions from the circuit board, and thus both a mounting operation and a dismounting operation are made simpler.

### BRIEF DESCRIPTION OF THE DRAWINGS

FIG. 1 (PRIOR ART) is an exploded view showing how to fasten a heat sink to a chip mounted on a circuit board;

FIG. 2 is an exploded view showing how to fasten a heat sink to an electronic device mounted on a circuit board with a fastening mechanism of a preferred embodiment of the present invention;

FIG. 3 is a cross-sectional view of FIG. 2; and

FIG. 4 is a schematic view showing how to dismount a fastening mechanism of a preferred embodiment of the present invention.

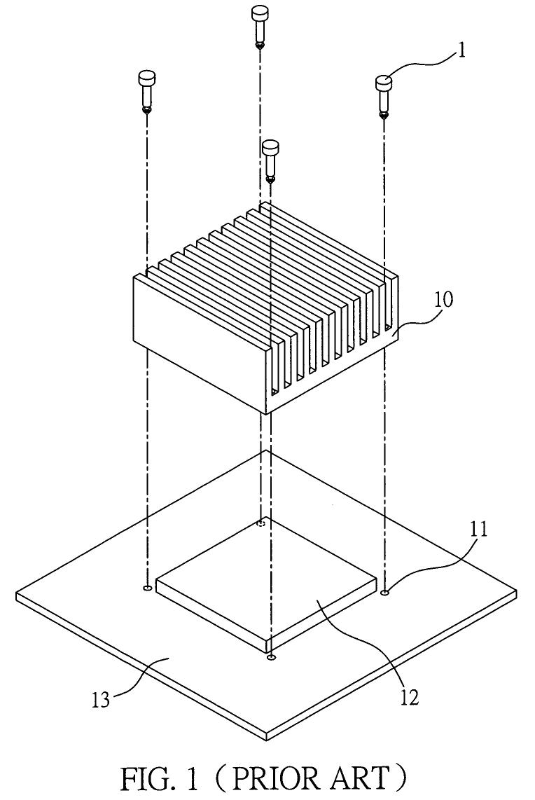

### DETAILED DESCRIPTION OF THE PREFERRED EMBODIMENT

The following specific embodiment is provided to illustrate the present invention. Others ordinarily skilled in the art can readily gain an insight into other advantages and features of the present invention based on the contents disclosed in this specification.

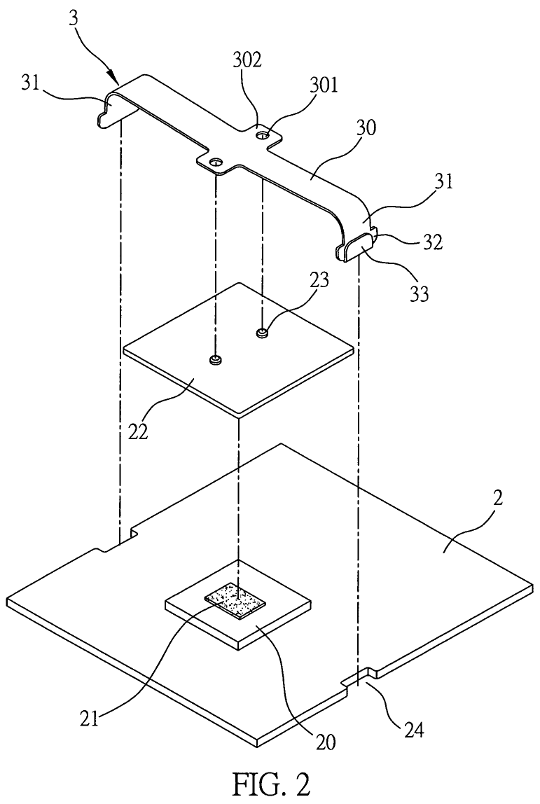

Referring to FIG. 2, which is an exploded view showing how to fasten a heat sink 22 to an electronic device 20 mounted on a circuit board 2 with a fastening mechanism 3 of the present invention. The heat sink 22 comprises a first positioning portion 23. Two opposite sides of the circuit board 2 are disposed with a notch 24 each. The electronic device 20 is, for example, a semiconductor chip coated with thermally conductive adhesive 21 for transferring to the heat sink 22 any heat generated by the electronic device 20 with a view to speeding up heat dissipation. The fastening mechanism 3 comprises a body 30, at least two bending portions 31, and at least two snap-fit portions 32. The body 30 presses on the heat sink 22. The bending portions 31 are disposed at both ends of the body 30 respectively. The snap-fit portions 32 are disposed at both ends of the bending portions 31 respectively.

The fastening mechanism 3 is, for example, a metal board, or any equivalent panel-shaped component characterized by thermal resistance and rigidity. Besides, the fastening mechanism 3 enables an increase in heat dissipation area of the electronic device 20.

The body 30 comprises a second positioning portion 301 corresponding in position to the first positioning portion 23. The body 30 presses on the heat sink 22, and thus the heat sink 22 is pressed against the electronic device 20. In this embodiment, the second positioning portion 301 is a hole, and the first positioning portion 23 is a protruding post. The second positioning portion 301 and the first positioning portion 23 correspond in position to each other and thereby couple with each other, so as to secure in position the body 30 to the heat sink 22 with a view to preventing the heat sink 22 from sliding. The second positioning portion 301 is, approximately, centrally disposed in the body 30. A protruding portion 302 extending outward is centrally disposed in the body 30. The second positioning portion 301 is disposed in the protruding portion 302.

A point to note is that, although this embodiment uses a hole as the second positioning portion 301 and a protruding post as the first positioning portion 23, persons ordinarily skilled in the art obviously know that any protruding post protruding from the surface of the body 30 and corresponding in position to the first positioning portion 23 exemplified by a hole can be formed on the body 30 by stamping, without being limited by the description of this embodiment. Of course, the shape and the position of the protruding portion 302 are not limited by this embodiment either.

The bending portions 31 correspond in position to and stride over the notches 24 respectively; also, the bending portions 31 extend and bend downward from both ends of the body 30. In this embodiment, the bending portions 31 extend and bend downward 90 degrees from both ends of the body 30, and the number of the bending portions 31 is two. However, in other embodiments, the bending portion 31 extend and bend downward 90 degrees approximately from both ends of the body 30, and at least one bending portion 31 and one snap-fit portion 32 extend from the protruding portion 302 so as to enhance snap-fit engagement.

The snap-fit portions 32 are wider than the notches 24, for snap-fit engagement with the edges of the notches 24 of the circuit board 2. In this embodiment, the snap-fit portions 32 extend outward from both ends of the bending portions 31 and assume a T shape or any other shapes.

The fastening mechanism 3 further selectively comprises an operating portion 33 disposed on an outer side of at least one of the snap-fit portions 32. In this embodiment, the operating portion 33 bends upward from the end of the snap-fit portion 32 and assumes a barb shape, and thus the operating portion 33 assumes a U shape approximately so as to avoid concentration of stress.

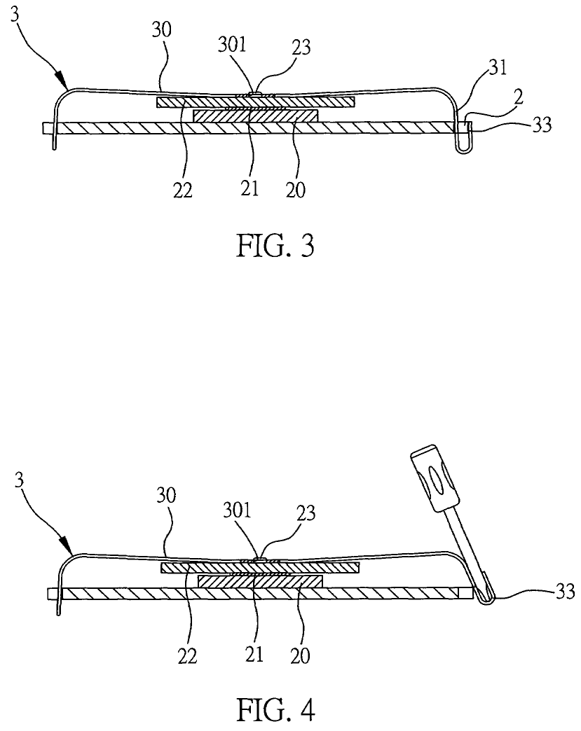

Referring to FIG. 3, which is a cross-sectional view showing how to mount the fastening mechanism 3 of the present invention, coupling the second positioning portion 301 to the first positioning portion 23 and snap-fit engagement of the snap-fit portions 32 with the edges of the notches 24 of the circuit board 2 allow the body 30 to press on the heat sink 22 and thereby firmly fasten the heat sink 22 to the electronic device 20, and in consequence a mounting operation can be quickly performed without using a tool.

Referring to FIG. 4, to dismount the fastening mechanism 3 from the circuit board 2, a user may use a tool 4, such as a slotted screwdriver, to actuate the operating portion 33, for example, pulling the operating portion 33 outward to separate the bending portion 31 from the notch 24 and thereby separate the snap-fit portion 32 from the bottom of the circuit board 2, thus dismounting the fastening mechanism 3 from the circuit board 2. Of course, the user may choose to pull by hand the snap-fit portion 32 from the bottom of the circuit board 2 so as to separate the snap-fit portion 32 from the bottom of the circuit board 2, depending on the structural strength of the fastening mechanism 3 designed to work with an intended heat sink. For instance, in the event that the fastening mechanism 3 is thin and of little structural strength, the fastening mechanism 3 can be dismounted by hand. However, in the event that the fastening mechanism 3 is of considerable structural strength, a slotted screwdriver or any other appropriate tool may be required to dismount the fastening mechanism 3.

Accordingly, as disclosed in the present invention, a fastening mechanism achieves snap-fit engagement with a circuit board by means of snap-fit portions disposed at both ends of the fastening mechanism. Also, as disclosed in the present invention, a body of the fastening mechanism presses on a heat sink and thus the heat sink is effectively fastened to an electronic device. As a result, the present invention prevents the heat sink from getting loosened under an external force. In addition, as disclosed in the present invention, to dismount the fastening mechanism, a user may actuate an operating portion and separate the corresponding snap-fit portion from the circuit board, or the user may actuate a snap-fit portion and separate the snap-fit portion from the circuit board, thus allowing the user to perform a mounting operation and a dismounting operation conveniently.

The aforesaid embodiment merely serves as the preferred embodiment of the present invention. It should not be construed as to limit the scope of the present invention. Hence, any other changes can be made in the present invention. It will be apparent to those ordinarily skilled in the art that all equivalent modifications or changes made, without departing from the spirit and the technical concepts disclosed by the present invention, should fall within the scope of the appended claims.

What is claimed is:

1. A fastening mechanism for fastening a heat sink to an electronic device mounted on a circuit board, the heat sink being disposed with a first positioning portion, the circuit board having two opposite sides each disposed with a notch, the fastening mechanism comprising:
a body for pressing on the heat sink, the body having a second positioning portion corresponding in position to the first positioning portion;
at least two bending portions disposed at both ends of the body respectively, and corresponding in position to and striding over the notches respectively; and
at least two snap-fit portions disposed at both ends of the bending portions respectively, and wider than the notches respectively, for snap-fit engagement with edges of the notches of the circuit board.

2. The fastening mechanism of claim 1, wherein the body is a metal board.

3. The fastening mechanism of claim 1, wherein the first positioning portion is a protruding post, and the second positioning portion is a hole corresponding in position and shape to the protruding post.

4. The fastening mechanism of claim 1, wherein the first positioning portion is a hole, and the second positioning portion is a protruding post corresponding in position and shape to the hole.

5. The fastening mechanism of claim 1, wherein the second positioning portion is centrally disposed in the body.

6. The fastening mechanism of claim 5, wherein a protruding portion extending outward is centrally disposed in the body and is disposed with the second positioning portion.

7. The fastening mechanism of claim 1, wherein the bending portions extend and bend downward from both ends of the body.

8. The fastening mechanism of claim 1, wherein the snap-fit portions extend outward from both ends of the bending portions.

9. The fastening mechanism of claim 1, further comprising an operating portion disposed on an outer side of at least one of the snap-fit portions.

10. The fastening mechanism of claim 9, wherein the operating portion bends upward from an end of the snap-fit portion and assumes a barb shape.
